(19) United States
(12) Patent Application Publication
(10) Pub. No.: US 2026/0190647 A1
(43) Pub. Date: Jul. 2, 2026

(54) DISPLAY DEVICE AND ELECTRONIC DEVICE INCLUDING THE SAME

(71) Applicant: Samsung Display Co., LTD., Yongin-si (KR)

(72) Inventors: Han Su KIM, Yongin-si (KR); Eun A YANG, Yongin-si (KR)

(21) Appl. No.: 19/419,038

(22) Filed: Dec. 14, 2025

(30) Foreign Application Priority Data
Dec. 30, 2024 (KR) 10-2024-0200666

(51) Int. Cl. H10K 59/122; G09G 3/20; H10K 59/38

(52) U.S. Cl. CPC H10K 59/122; G09G 3/2003; H10K 59/38; G09G 2320/0242

(57) ABSTRACT

A display device includes a light-emitting device, and a color control portion disposed on the light-emitting device. The color control portion includes a bank disposed in which a color control hole is defined, and a color control layer formed in the color control hole. A top surface of the bank includes a surface treatment region that includes a first surface treatment region next to a hole perimeter of the color control hole and having a first contact angle, and a second surface treatment region spaced apart from the hole perimeter with the first surface treatment region interposed therebetween and having a second contact angle greater than the first contact angle.

This application claims priority to Korean Patent Application No. 10-2024-0200666, filed on Dec. 30, 2024, and all the benefits accruing therefrom under 35 U.S.C. § 119, the content of which in its entirety is herein incorporated by reference.

### TECHNICAL FIELD

Embodiments of the disclosure relate to a display device and an electronic device including the same. More particularly, embodiments of the disclosure relate to a display device including a light-emitting device and a color control portion, and an electronic device including the same.

### BACKGROUND

In a display device such as an organic light-emitting diode (“OLED”) display device and a liquid crystal display (“LCD”) device, a display substrate including thin film transistors (“TFTs”) and various wirings may be provided, and a display structure including electrodes and emission layers may be formed on the display substrate.

For example, the OLED display device may include a light-emitting device including an organic emission layer. Additionally, a color filter may be added to improve image or color properties generated from the light-emitting device.

### SUMMARY

According to a feature of the disclosure, there is provided a display device having improved optical property and image reliability.

According to a feature of the disclosure, there is provided a method of manufacturing a display device having improved optical property and image reliability.

According to a feature of the disclosure, there is provided an electronic device including a display device with improved optical property and image reliability.

In an embodiment, a display device may include a light-emitting device, and a color control portion disposed on the light-emitting device. The color control portion may include a bank in which a color control hole is defined, and a color control layer formed in the color control hole. A top surface of the bank may include a surface treatment region that may include a first surface treatment region next (adjacent) to a hole perimeter of the color control hole and having a first contact angle, and a second surface treatment region spaced apart from the hole perimeter with the first surface treatment region interposed therebetween and having a second contact angle greater than the first contact angle.

In some embodiments, the first surface treatment region may include the hole perimeter, and the second surface treatment region may include an outermost perimeter of the surface treatment region.

In some embodiments, the second surface treatment region and the first surface treatment region may contact each other.

In some embodiments, the surface treatment region may further include a third surface treatment region spaced apart from the first surface treatment region with the second surface treatment region therebetween. The third surface treatment region may have a third contact angle greater than the second contact angle of the second surface treatment region.

In some embodiments, the first surface treatment region may include the hole perimeter, and the third surface treatment region may include an outermost perimeter of the surface treatment region.

In some embodiments, the color control hole may include a first color control hole and a second color control hole next (adjacent) to each other. The color control layer may include a first color control layer and a second color control layer having different colors from each other and filling the first color control hole and the second color control hole, respectively.

In some embodiments, the surface treatment region may be provided in plural, a surface treatment region surrounding the first color control hole among surface treatment regions and a surface treatment region surrounding the second color control hole among the surface treatment regions may be separated with a separation distance interposed therebetween on a portion of the top surface of the bank between the first color control hole and the second color control hole.

In some embodiments, a portion of the top surface of the bank included in the separation distance may have a contact angle smaller than the first contact angle.

In some embodiments, a distance of the surface treatment region extended from a hole perimeter of the first color control hole and a distance of the surface treatment region extended from a hole perimeter of the second color control hole may each be less than ½ of a width of the portion of the top surface of the bank between the first color control hole and the second color control hole.

In some embodiments, the color control hole may include a first color control hole, a second color control hole and a third color control hole. The color control layer may include a first color control layer, a second color control layer and a third color control layer having different colors from each other and filling the first color control hole, the second color control hole and the third color control hole, respectively.

In some embodiments, the first color control layer, the second color control layer and the third color control layer may serve as a red color layer, a green color layer and a blue color layer, respectively.

In some embodiments, an area of the third color control layer may be smaller than an area of each of the first color control layer and the second color control layer.

In some embodiments, the color control portion may further include a base layer on which the bank and the color control layer are arranged, and a light-scattering layer disposed between the color control layer and the base layer to selectively overlap the first color control layer and the second color control layer among the first color control layer, the second color control layer and the third color control layer.

In some embodiments, the display device may not include a polarizing plate.

In an embodiment, a display device may include a light-emitting device, and a color control portion disposed on the light-emitting device. The color control portion may include a bank in which a color control hole is defined, and a color control layer formed in the color control hole. A top surface of the bank may include a surface treatment region having a contact angle that increases in a region farther from a hole perimeter of the color control hole in a radial direction of the color control hole.

In some embodiments, the surface treatment region may be provided in plural, and a plurality of surface treatment regions may have contact angles that increase stepwise from the hole perimeter.

In some embodiments, the contact angle of the surface treatment region may continuously increase from the hole perimeter.

In some embodiments, the surface treatment region may be provided in plural, the color control hole may be provided in plural, and a plurality of color control holes may be surrounded by a plurality of surface treatment regions, respectively. The surface treatment regions may be spaced apart from each other on the top surface of the bank.

An electronic device may include a display device, a memory, and a processor executing data included in the memory to control an operation of the display device. The display device may include a light-emitting device, and a color control portion disposed on the light-emitting device. The color control portion may include a bank in which a color control hole is defined, and a color control layer formed in the color control hole. A top surface of the bank may include a surface treatment region that may include a first surface treatment region next (adjacent) to a hole perimeter of the color control hole and having a first contact angle, and a second surface treatment region spaced apart from the hole perimeter with the first surface treatment region interposed therebetween and having a second contact angle greater than the first contact angle.

In some embodiments, the electronic device may include virtual reality or augmented reality glasses, a smartphone, a tablet personal computer, a laptop, a television (“TV”), a desk monitor, smart glasses, a head-mounted display, a smart watch, or a vehicle display.

By embodiments of the disclosure, surface treatment regions having different contact angles may be formed on a top surface of a bank in which a color control hole is defined. According to configurations, a colorant droplet dropped on the top surface of the bank may be guided into the color control hole by the surface treatment regions.

Thus, desired optical/color properties of a color control portion may be effectively implemented while preventing color mixing between color control layers of different colors, and non-filling of the color control hole.

### BRIEF DESCRIPTION OF THE DRAWINGS

The above and other embodiments, advantages and features of this disclosure will become more apparent by describing in further detail embodiments thereof with reference to the accompanying drawings, in which:

FIG. 1 is a schematic plan view of an embodiment of a display device.

FIG. 2 is a schematic plan view illustrating an embodiment of arrangement of color control portions in a display device.

FIG. 3 is a schematic cross-sectional view of an embodiment of a display device.

FIG. 4 is a schematic cross-sectional view illustrating an embodiment of a light emitting device of a display device.

FIG. 5 is a schematic plan view illustrating an embodiment of a color control hole and a top surface of a bank.

FIG. 6 is a schematic plan view illustrating an embodiment of a color control hole and a top surface of a bank.

FIG. 7 is a schematic cross-sectional view illustrating an embodiment of formation of a color control layer.

FIG. 8 is a schematic plan view illustrating an embodiment of a color control hole and a top surface of a bank.

FIG. 9 is a graph illustrating an embodiment of a contact angle profile of a surface treatment region.

FIG. 10 is an exploded perspective view illustrating an embodiment of an electronic device.

FIG. 11 is a block diagram of an embodiment of an electronic device.

FIG. 12 is a schematic diagram of an embodiment of electronic devices.

### DETAILED DESCRIPTION

Hereinafter, embodiments of the disclosure will be described in more detail with reference to the attached drawings. The same reference numerals may l be used for indicating the same elements in the drawings, and repeated descriptions of the same elements may be omitted. Embodiments disclosed in the attached drawings are exemplary, and is to be understood to include all modifications, equivalents and substitutes included in the spirit and technical scope of the disclosure.

The terms “on”, “connected”, “coupled,” etc., used herein refers to a direct placement/connection/combination, and also refers to a case where another element is interposed two different elements.

The terms such as “first”, “second”, “below”, “lower”, “upper”, “above,” etc., are used in a relative sense to distinguish different elements or positions, and do not specify an absolute position or an absolute order.

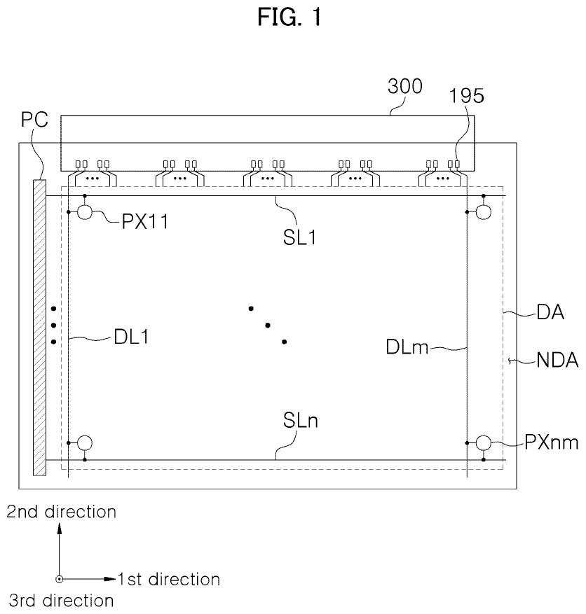

FIG. 1 is a schematic plan view of an embodiment of a display device. For example, FIG. 1 is a plan view illustrating an embodiment of an arrangement of pixels of a display device.

In FIG. 1, a first direction and a second direction may refer to two directions parallel to a display surface of a display device and perpendicular to each other. In an embodiment, the first direction may correspond to an X-direction (a row direction), and the second direction may correspond to a Y-direction (a column direction) of the display device, for example. A third direction may be perpendicular to the first direction and the second direction. The third direction may correspond to a Z-direction (a thickness direction) of the display device.

The definitions of the directions described above may be equally applied to the accompanying drawings.

Referring to FIG. 1, a plurality of pixels PX11 to PXnm (n and m are natural numbers) may be disposed in a display area DA of the display device.

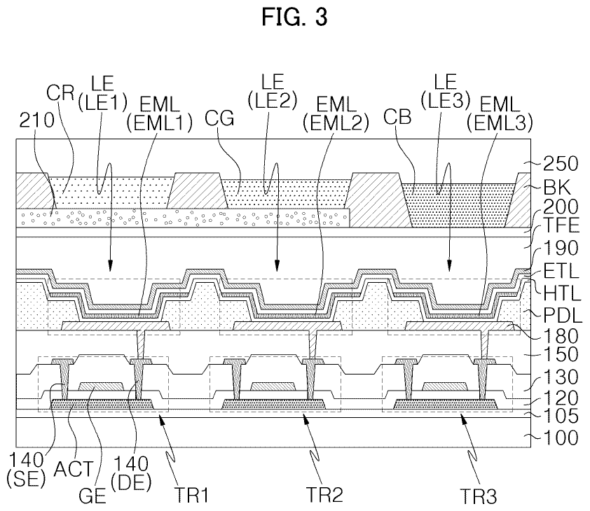

In embodiments, a pixel circuit including scan lines (or gate lines) SL1 to SLn forming first to n^{th} rows and data lines DL1 to DLm forming first to m^{th} columns may be arranged on a base substrate 100 (refer to FIG. 3) of the display device. Each of the pixels PX11 to PXnm may be connected to a scan line of a corresponding row among a plurality of scan lines SL1 to SLn and a data line of a corresponding column among a plurality of data lines DL1 to DLm.

Each of the pixels PX11 to PXnm may further include a pixel driving circuit including a transistor and a light-emitting device as described below. Although not illustrated in detail in FIG. 1, the pixel circuit may further include wirings such as a power line, a ground line, or the like.

In FIG. 1, data lines DL1 to DLm extend in the second direction, and scan lines SL1 to SLn extend in the first direction, but the inventive concepts are not limited to the construction illustrated in FIG. 1.

A peripheral circuit PC may be disposed in the non-display area NDA corresponding to a peripheral area with respect to the display area DA. In an embodiment, the peripheral circuit PC may include a gate driving circuit, for example. The gate driving circuit may be integrated into the display device by an oxide semiconductor gate (“OSG”) driver circuit process, an amorphous silicon gate (“ASG”) driver circuit process, or a polysilicon gate (“PSG”) driver circuit process.

The peripheral circuit PC may further include a data driver, a gate driver, a light-emitting driver, a power voltage generator, a timing controller, or the like.

The display device may further include a printed circuit board 300. Pads 195 of the pixel circuit may be assembled on one side of the non-display area NDA. A printed circuit board 300 may be electrically connected to the pixel circuit through the pads 195. In an embodiment, the printed circuit board 300 may be electrically connected to the pads 195 by a heating-compression process using a conductive intermediate structure such as an anisotropic conductive film (“ACF”), for example.

An integrated circuit (“IC”) such as a data driving circuit may be disposed on the printed circuit board 300. In some embodiments, an integrated circuit IC chip in the form of a chip-on-film (“COF”) may be disposed (e.g., mounted) on the printed circuit board 300.

Hereinafter, elements/structures of the display device of the disclosure may be described using an embodiment of an organic light-emitting display device. However, the display device disclosed herein may be applied to various types of display devices such as an inorganic light-emitting display device and a quantum dot light-emitting display device, or the like.

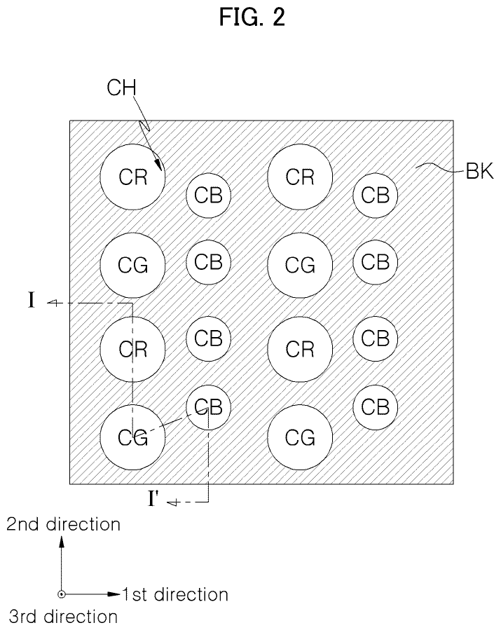

FIG. 2 is a schematic plan view illustrating an embodiment of arrangement of color control portions of a display device.

Referring to FIG. 2, e.g., a color control portion may be disposed on an encapsulation layer TFE (refer to FIG. 3) of the display device. The color control portion may include a color control layer and a bank BK that distinguishes/defines the color control layer.

In an embodiment, the bank BK may include a polymer resin material or a photoresist material having light-shielding properties, and may be formed by a photo-lithography process including exposure and development processes, for example.

The bank BK may include color control holes CH. The color control holes CH may be defined in the bank BK by the photo-lithography process. The color control layer may be disposed in each of the color control holes CH.

The color control layer may include a first color control layer CR, a second color control layer CG, and a third color control layer CB. In embodiments, the color control layer may serve as a colored layer of a color filter.

The color control layer may be formed using a colored resin composition including a binder resin and a colorant (e.g., a dye and/or a pigment). In embodiments, the color control layer may be formed by filling the colored resin composition into the color control hole CH by a printing process such as an inkjet process.

In some embodiments, the first color control layer CR, the second color control layer CG, and the third color control layer CB may be formed as a red color layer, a green color layer, and a blue color layer, respectively.

In an embodiment, as illustrated in FIG. 2, the first color control layer CR and the second color control layer CG may be alternately and repeatedly arranged in the second direction, for example. The third color control layer CB may have an area smaller than that of each of the first color control layer CR or the second color control layer CG. The third color control layer CB may be next (adjacent) to the first color control layer CR or the second color control layer CG in the second direction.

In an embodiment, the first color control layer CR and the second color control layer CG may be alternately and repeatedly arranged to form a color control column, for example. The color control column may be repeatedly arranged in the first direction. The third color control layers CB may be repeatedly arranged in the second direction between the color control columns next (adjacent) to each other.

In an embodiment, a color control group may be defined by one first color control layer CR and one second color control layer CG neighboring in the second direction, and two third color control layers CB next (adjacent) to the one first color control layer CR and the one second color control layer CG. The color control group may be repeatedly arranged in the first direction and the second direction.

The arrangement of the color control layers described with reference to FIG. 2 is provided in an embodiment, and the structure of the color control portion included in the display device of the inventive concepts is not limited to that illustrated in FIG. 2.

FIG. 3 is a schematic cross-sectional view of an embodiment of a display device. For example, FIG. 3 is a cross-sectional view taken along line I-I′ of FIG. 2 in a thickness direction (the third direction).

Referring to FIG. 3, the display device may include a base substrate 100, a pixel circuit, and a light-emitting device LE.

The base substrate 100 may serve as a back-plane substrate of a display device. A glass substrate or a plastic substrate may be used as the base substrate 100. In some embodiments, the base substrate 100 may include a polymer material having transparency and flexibility. In this case, the base substrate 100 may be used in a transparent flexible display device.

In an embodiment, the base substrate 100 may include a polymer material such as polyimide, polysiloxane, an epoxy resin, an acrylic resin, polyester, or the like, for example. In an embodiment, the base substrate 100 may include polyimide.

A buffer layer 105 may be formed on a top surface of the base substrate 100. Moisture penetrating through the base substrate 100 may be blocked by the buffer layer 105, and diffusion of impurities between the base substrate 100 and structures formed on the base substrate 100 may also be blocked by the buffer layer 105. The buffer layer 105 may be entirely formed over the display area DA and the non-display area NDA of the base substrate 100, and may cover an entirety of the top surface of the base substrate 100.

The buffer layer 105 may include, e.g., an inorganic insulating material such as silicon oxide, silicon nitride, or silicon oxynitride. These may be used alone or in any combinations thereof. In some embodiments, the buffer layer 105 may have a stacked structure including a silicon oxide layer and a silicon nitride layer. The buffer layer 105 may be formed by a deposition process such as a chemical vapor deposition (“CVD”) process, a sputtering process, an atomic layer deposition (“ALD”) process, or the like, to include the inorganic insulating material described above.

In some embodiments, the buffer layer 105 may include an organic layer, and may have a multi-layered structure of an organic layer and an inorganic layer.

The pixel circuit may include wirings including the scan lines and the data lines described with reference to FIG. 1, and transistors TR1, TR2 and TR3 that electrically interact with the wirings. The transistors TR1, TR2 and TR3 may be electrically connected to light-emitting devices LE1, LE2 and LE3.

The transistors TR1, TR2 and TR3 may include an active layer ACT, a gate insulation layer 120 and a gate electrode GE.

The active layer ACT may be disposed on the buffer layer 105, and may be patterned by a photo-lithography process to be repeatedly/regularly arranged at each pixel. The active layer ACT may include a silicon compound such as polysilicon or amorphous silicon. A p-type dopant or an n-type dopant may be doped in a partial region of the active layer ACT, so that the active layer ACT may include a source region, a drain region, and a channel region.

The active layer ACT may include an oxide semiconductor such as indium gallium zinc oxide (“IGZO”), zinc tin oxide (“ZTO”), or ITZO.

The gate insulation layer 120 may be formed on the active layer ACT, and the gate electrode GE may be stacked on the gate insulation layer 120. As illustrated in FIG. 3, the gate insulation layer 120 may be provided continuously and commonly in a plurality of transistors TR1, TR2 and TR3 or pixels of different colors. In an alternative embodiment, the gate insulation layer 120 may be formed in a pattern shape partially covering each active layer ACT.

The gate electrode GE may overlap the channel region of the active layer ACT in the third direction. A scan signal may be transmitted from the scan line through the gate electrode GE.

The gate insulation layer 120 may be formed by the above-mentioned deposition process to include an inorganic insulating material such as silicon oxide, silicon nitride, silicon oxynitride, or the like.

In some embodiments, the source region and the drain region may be formed in the active layer ACT by the gate electrode GE as an ion implantation mask.

An insulating interlayer 130 covering the gate electrode GE and the gate insulation layer 120 may be formed on the active layer ACT. A connection electrode 140 being in contact with or electrically connected to the active layer ACT may be formed on the insulating interlayer 130.

The insulating interlayer 130 may be formed by the above-mentioned deposition process to include an inorganic insulating material such as silicon oxide, silicon nitride, silicon oxynitride, or the like. The insulating interlayer 130 may be formed in a single-layered structure or a multi-layered structure including different materials from each other.

In some embodiments, when the gate insulation layer 120 has the individual pattern shape and the active layer ACT includes the oxide semiconductor, hydrogen (H) included in the insulating interlayer 130 may be diffused or transferred to the active layer ACT when forming the insulating interlayer 130. Accordingly, a carrier concentration may be increased by hydrogen, and thus the source region and the drain region may be formed at side portions of the active layer ACT.

The connection electrode 140 may penetrate the insulating interlayer 130, and may be connected to the active layer ACT. The connection electrode 140 may also penetrate the gate insulation layer 120.

The connection electrode 140 may include a source electrode SE connected to or in contact with the source region of the active layer ACT, and a drain electrode DE connected to or in contact with the drain region of the active layer ACT.

Contact holes may be defined by partially etching the insulating interlayer 130. In an embodiment, the contact holes exposing the source region and the drain region, respectively, may be defined, for example. A metal layer filling the contact holes may be formed on the insulating interlayer 130, and the metal layer may be partially etched to form the source electrode SE and the drain electrode DE. In an embodiment, a data signal may be transferred from the data line through the source electrode SE, for example.

The gate electrode GE and the connection electrode 140 may include a metal such as Ag, Mg, Al, W, Cu, Ni, Cr, Mo, Ti, Pt, Ta, Nd, Sc, or the like, any alloys thereof, or a nitride thereof. The gate electrode GE and the connection electrode 140 may be formed by the above-mentioned deposition process such as a sputtering process.

A planarization layer 150 covering the connection electrodes 140 may be formed on the insulating interlayer 130. The planarization layer 150 may accommodate a via portion electrically connecting the pixel electrode 180 to the drain electrode DE.

In some embodiments, the planarization layer 150 may include an organic material such as polyimide, an epoxy resin, an acrylic resin, polyester, a siloxane resin, benzocyclobutene (“BCB”), or the like. The planarization layer 150 may be formed by a coating process such as a spin coating process or the above-mentioned deposition process described above.

The pixel electrode 180 may be formed in each pixel to be electrically connected to the transistor. The pixel electrode 180 may be formed on the planarization layer 150 to be electrically connected to the drain electrode DE.

In an embodiment, the planarization layer 150 may be partially etched to define a via hole exposing a top surface of the drain electrode DE, for example. A conductive layer filling the via hole and including a metal or a transparent conductive oxide may be formed on a top surface of the planarization layer 150. The conductive layer may be etched to form the pixel electrode. The pixel electrode 180 may include the via portion filling the via hole.

The pixel electrode 180 may serve as an anode, and may include a relatively high work function conductive material capable of promoting hole injection. The pixel electrode 180 may be formed as a transmissive electrode. The pixel electrode 180 may include a transparent conductive oxide such as indium tin oxide (“ITO”), indium zinc oxide (“IZO”), zinc oxide (ZnO), indium tin oxide (“ITZO”), or the like.

The pixel electrode 180 may be formed as a translucent electrode or a reflective electrode. The pixel electrode 180 may include a metal selected from Ag, Mg, Cu, Al, Pt, Pd, Au, Ni, Nd, Ir, Cr, Li, Ca, Mo, Ti, W, In, Sn, and Zn, or an alloy or a compound (e.g., LiF) including at least one therefrom.

The pixel electrode 180 may have a single-layered structure or a multi-layered structure. In an embodiment, the pixel electrode 180 may have a triple-layered structure of ITO/Ag/ITO, for example.

A pixel defining layer PDL exposing a top surface of the pixel electrode 180 may be formed on the planarization layer 150. The pixel defining layer PDL may be formed to at least partially expose the top surface of the pixel electrode 180 so that a pixel may be defined. The pixel defining layer PDL may cover a peripheral portion of the pixel electrode 180.

In an embodiment, a pixel region or a light-emitting region may be defined by a sidewall of the pixel defining layer PDL, for example. A first pixel including the first transistor TR1 and the first light-emitting device LE1, a second pixel including the second transistor TR2 and the second light-emitting device LE2, and a third pixel including the third transistor TR3 and the third light-emitting device LE3 may be separated from each other and defined by the pixel defining layer PDL.

In some embodiments, the first pixel, the second pixel and the third pixel may correspond to a red pixel, a green pixel, and a blue pixel, respectively.

The pixel defining layer PDL may include, e.g., an organic material such as a polysiloxane resin, a polyimide resin, an acrylic resin, or the like. The pixel defining layer PDL may include a colorant material such as a black pigment/dye dispersed in the resin material.

In some embodiments, the pixel defining layer PDL may have a stepped structure as illustrated in FIG. 3.

An emission layer EML may be disposed on the exposed surface of the pixel electrode 180. In some embodiments, the emission layer EML may include an organic light-emitting material independently patterned for each red pixel, a green pixel and a blue pixel to generate different colored lights for each pixel. The emission layer EML may include a first emission layer EML1 that may be included in the first pixel and may include a red organic light-emitting material, a second emission layer EML2 that may be included in the second pixel and may include a green organic light-emitting material, and a third emission layer EML3 that may be included in the third pixel and may include a blue organic light-emitting material.

In an embodiment, the organic light-emitting material may include a host material excited by holes and electrons, and a dopant material increasing luminous efficiency through absorption and release of energy, for example.

In some embodiments, a hole transport layer HTL may be disposed between the pixel electrode 180 and the emission layer EML. An electron transport layer ETL may be disposed on the emission layer EML.

The hole transport layer HTL and the electron transport layer ETL may extend continuously and commonly throughout a plurality of the light-emitting devices LE and the pixels.

In an embodiment, the hole transport layer HTL may include a hole transporting material such as 4,4′,4″-[tris(3-methylphenyl)phenylamino] triphenylamine (“m-MTDATA”), 4,4′4″-tris(N,N-diphenylamino)triphenylamine (“TDATA”), 4,4′,4″-tris[N(2-naphthyl)-N-phenylamino]-triphenylamine (“2-TNATA”), N,N′-di(naphthalene-l-yl)-N,N′-diphenyl-benzidine (“NPB”), N,N′-bis(3-methylphenyl)-N,N′-diphenyl-[1,1′-biphenyl]-4,4′-diamine (“TPD”), 4,4′,4″-tris(N-carbazolyl)triphenylamine (“TCTA”), poly(3,4-ethylenedioxythiophene)/poly(4-styrenesulfonate) (“PEDOT/PSS”), or the like, for example.

In an embodiment, the electron transport layer ETL may include an electron transporting material such as an anthracene-based compound, tris(8-hydroxyquinolinato)aluminum (“Alq₃”), 1,3,5-Tri(1-phenyl-1H-benzo[d]imidazol-2-yl)benzene (“TPBi”), 2,9-dimethyl-4,7-diphenyl-1,10-phenanthroline (“BCP”), 4,7-diphenyl-1,10-phenanthroline (“Bphen”), 3-(4-biphenylyl)-4-phenyl-5-tert-butylphenyl-1,2,4-triazole (“TAZ”), 4-(naphthalen-1-yl)-3,5-diphenyl-4H-1,2,4-triazole (“NTAZ”), 2-(4-biphenylyl)-5-(4-tert-butylphenyl)-1,3,4-oxadiazole (“tBu-PBD”), bis(2-methyl-8-quinolinolato-N1,O8)-(1,1′-biphenyl-4-olato)aluminum (“BAlq”), or the like, for example.

The emission layer EML, the hole transport layer HTL, and/or the electron transport layer ETL may be formed by a process such as a thermal deposition, a vapor deposition, a vacuum deposition, a spin coating, an inkjet printing, a laser printing, a casting, a laser thermal transfer, or the like. In an embodiment, a selective deposition of the emission layer EML for each pixel may be effectively performed by the pixel defining layer PDL having the stepped structure, for example.

In some embodiments, a hole injection layer may be further formed between the pixel electrode 180 and the hole transport layer HTL. An electron injection layer may be further formed between a counter electrode 190 and the electron transport layer ETL.

The counter electrode 190 may be disposed on the pixel defining layer PDL and the emission layer EML. The counter electrode 190 may be formed on the electron transport layer ETL.

The counter electrode 190 may be a common electrode continuously and commonly included in a plurality of the light-emitting regions or the pixels.

The counter electrode 190 may serve as an electron injection electrode or a cathode. The counter electrode 190 may include a metal, an alloy, an electrically conductive compound, or the like, having a relatively low work function.

In an embodiment, the counter electrode 190 may include lithium (Li), silver (Ag), magnesium (Mg), aluminum (Al), aluminum-lithium (Al-Li), calcium (Ca), magnesium-indium (Mg-In), magnesium-silver (Mg-Ag), ytterbium (Yb), silver-ytterbium (Ag-Yb), ITO, IZO, or the like. These may be used alone or in combination of two or more therefrom, for example.

The counter electrode 190 may be formed as a transmissive electrode, a translucent electrode, or a reflective electrode. The counter electrode 190 may have a single-layered structure or a multi-layered structure.

The light-emitting device LE may be defined by the stacked structure of the pixel electrode 180, the hole transport layer HTL, the emission layer EML, the electron transport layer ETR, and the counter electrode 190. In an embodiment, the light-emitting device LE may be electrically connected to the transistor of each pixel through the drain electrode DE, for example.

The light-emitting devices LE may include the first light-emitting device LE1, the second light-emitting device LE2, and the third light-emitting device LE3 including the first emission layer EML1, the second emission layer EML2 and the third emission layer EML3, respectively. In some embodiments, the first light-emitting device LE1, the second light-emitting device LE2, and the third light-emitting device LE3 may be provided as a red light-emitting device, a green light-emitting device, and a blue light-emitting device, respectively.

An encapsulation layer TFE covering the light-emitting devices LE1, LE2 and LE3 may be disposed on the counter electrode 190. The encapsulation layer TFE may be disposed on the pixel defining layer PDL and the light-emitting devices LE1, LE2 and LE3 to protect the light-emitting devices LE1, LE2 and LE3 from moisture or oxygen.

The encapsulation layer TFE may include an inorganic layer including silicon nitride (SiNx), silicon oxide (SiOx), indium tin oxide, indium zinc oxide, or any combination thereof; an organic layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., aliphatic glycidyl ether (“AGE”)), or any combination thereof; or a combination of the inorganic and organic layers.

The encapsulation layer TFE may be formed in a single-layered structure or a multi-layered structure. In some embodiments, the encapsulation layer TFE may have a sequential stacked structure of a first inorganic layer, an organic layer and a second inorganic layer.

The color control portion may be disposed on the encapsulation layer TFE. The color control portion may include the base layer 200, the bank BK formed on the base layer 200, and the color control layers CR, CG and CB defined by the bank BK.

The base layer 200 may serve as a substrate for the bank BK and the color control layers CR, CG and CB, and the base layer 200 may include the above-mentioned inorganic insulating material.

As described with reference to FIG. 2, the first color control layer CR, the second color control layer CG and the third color control layer CB may include a red colored layer, a green colored layer and a blue colored layer, respectively. The first color control layer CR, the second color control layer CG and the third color control layer CB may overlap the first light-emitting device LE1, the second light-emitting device LE2 and the third light-emitting device LE3, respectively, in the third direction.

The color control portion may further include a light-scattering layer 210 disposed between the color control layer and the base layer 200. The light-scattering layer 210 may include a binder resin layer and light scattering particles such as TiO₂, ZnO, Al₂O₃, SiO₂, hollow silica, or the like, dispersed in the binder resin layer.

In some embodiments, the light-scattering layer 210 may be selectively disposed under the first color control layer CR and the second color control layer CG, and may not be disposed under the third color control layer CB. Accordingly, luminous efficiency may be relatively increased in the blue light-emitting region, and optical reliability may be improved by preventing reflection of external light in the red and green light-emitting regions.

The color control portion may further include a protective layer 250 covering the bank BK and the color control layers CR, CG and CB. The protective layer 250 may include the inorganic insulating material and/or the organic insulating material described above.

In embodiments, the color control portion may serve as a color filter structure. The first color control layer CR, the second color control layer CG and the third color control layer CB may serve as a red color filter, a green color filter and a blue color filter, respectively.

In embodiments, the color control portion may be formed as an on-cell film (“OCF”), and the display device may have a pol-less structure that does not include a polarizing plate.

The color control portion may be disposed so that the first color control layer CR, the second color control layer CG and the third color control layer CB may be superimposed over the red light-emitting device, the green light-emitting device and the blue light-emitting device, respectively. Thus, reflection of external light may be sufficiently reduced and color purity of each pixel may be enhanced without using the polarizing plate.

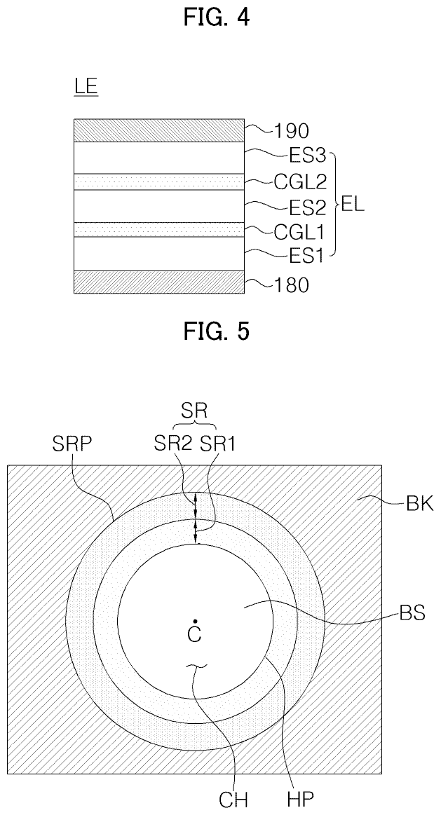

FIG. 4 is a schematic cross-sectional view illustrating an embodiment of a light-emitting device of a display device.

Referring to FIG. 4, the light-emitting device LE of the display device described with reference to FIG. 3 may have a tandem structure.

As illustrated in FIG. 4, the light-emitting device LE may include a light-emitting portion EL disposed between the first electrode 180 and the second electrode 190, and the light-emitting portion EL may include a plurality of light-emitting structures ES1, ES2 and ES3. Each of the light-emitting structures ES1, ES2 and ES3 may include the hole transport layer HTL, the emission layer EML, and the electron transport layer ETL.

Charge generation layers CGL1 and CGL2 may be disposed between neighboring light-emitting structures ES1, ES2 and ES3. The charge generation layers CGL1 and CGL2 may include a p-type charge generation layer and/or an n-type charge generation layer. The charge generation layers CGL1 and CGL2 may include a first charge generation layer CGL1 between the first light-emitting structure ES1 and the second light-emitting structure ES2, and a second charge generation layer CGL2 between the second light-emitting structure ES2 and the third light-emitting structure ES3.

In embodiments, the first light-emitting structure ES1, the first charge generation layer CGL1, the second light-emitting structure ES2, the second charge generation layer CGL2, the third light-emitting structure ES3, and the counter electrode 190 may be sequentially stacked from the top surface of the pixel electrode 180.

The light-emitting portion EL included in the light-emitting device LE may be provided as a common layer of the first to third light-emitting devices LE1, LE2 and LE3. In some embodiments, blue light or white light may be emitted from the light-emitting portion EL, and color for each pixel may be implemented by the above-described color control portion described above.

FIG. 4 illustrates an embodiment of a triple-layered tandem structure light-emitting device LE, but the light-emitting device LE may have a tandem structure of two layers, or four or more layers.

FIG. 5 is a schematic plan view illustrating an embodiment of a color control hole and a top surface of a bank.

Referring to FIG. 5, as described above, the color control portion may include the bank BK in which the color control hole CH is defined. The color control layer may be formed in the color control hole CH as described above.

The color control hole CH may have a circular shape or an elliptical shape in a plan view. A top surface of the bank BK may include a hole perimeter HP of the color control hole CH. The hole perimeter HP may be defined as a boundary between a sidewall of the bank BK in the color control hole CH and the top surface of the bank BK.

By embodiments, the top surface of the bank BK may include a surface treatment region SR covering a region of a predetermined distance from the hole perimeter HP. In a plan view, the surface treatment region SR may have a ring shape surrounding a bottom surface BS of the color control hole CH. In an embodiment, the surface treatment region SR may have an outermost perimeter SRP, for example. The outermost perimeter SRP may be a perimeter spaced apart from the hole perimeter HP by the predetermined distance. The surface treatment region SR may be defined as a region between the hole perimeter HP and the outermost perimeter SRP.

In an embodiment, the surface treatment region SR may extend from the hole perimeter HP in a radial direction from a center C of the bottom surface BS of the color control hole CH, for example.

In embodiments of the disclosure, a contact angle of a region including the hole perimeter HP in the surface treatment region SR may be smaller than a contact angle of a region including the outermost perimeter SRP. In some embodiments, a surface energy of a region including the hole perimeter HP in the surface treatment region SR may be greater than a surface energy of a region including the outermost perimeter SRP.

In embodiments, the surface treatment region SR may include a first surface treatment region SR1 and a second surface treatment region SR2 sequentially disposed in an outer direction of the color control hole CH from the hole perimeter HP. A contact angle (a second contact angle) of the second surface treatment region SR2 may be greater than a contact angle (a first contact angle) of the first surface treatment region SR1.

The first surface treatment region SR1 may include the hole perimeter HP. The second surface treatment region SR2 may include the outermost perimeter SRP.

The surface treatment region SR may be formed by a chemical surface treatment or a physical surface treatment on a partial region of the top surface of the bank BK.

In embodiments, the chemical surface treatment may include a hexamethyldisilazane (“HMDS”) treatment. In an embodiment, after masking the top surface of the bank BK except for a predetermined region on the top surface of the bank BK on which the surface treatment region is formed, the predetermined region may be surface-treated by supplying an HMDS gas, for example. Accordingly, the surface treatment region SR having an increased hydrophobicity and contact angle relative to those of a remaining region may be formed.

In an embodiment, a degree of increase in hydrophobicity and contact angle may be controlled by adjusting a supply amount or concentration of the HMDS gas, for example. Accordingly, the first surface treatment region SR1 and the second surface treatment region SR2 having different contact angles may be formed.

In an embodiment, the physical surface treatment may include a masking grinding or a photo-patterning for the predetermined region of the top surface of the bank BK. The physical surface treatment may increase the contact angle by changing a surface roughness and a distribution of irregularities in the predetermined region of the top surface of the bank BK.

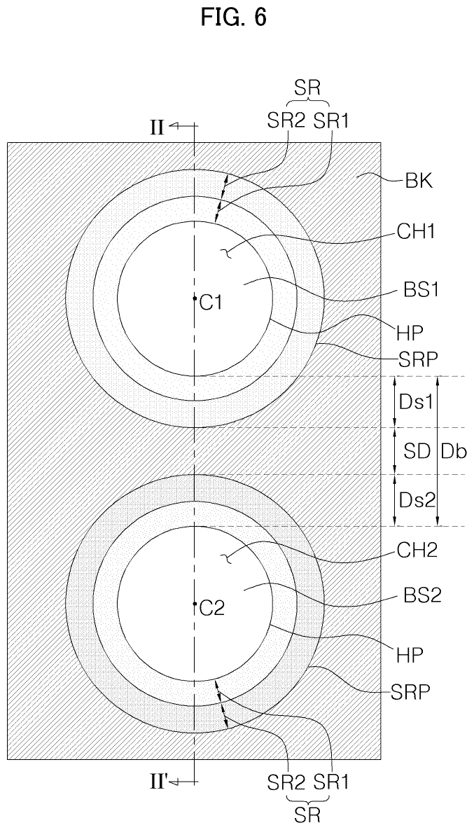

FIG. 6 is a schematic plan view illustrating an embodiment of a color control hole and a top surface of a bank.

Referring to FIG. 6, a first color control hole CH1 and a second color control hole CH2 next (adjacent) to each other may be defined in the bank BK. The first color control layer CR and the second color control layer CG may be formed in the first color control hole CH1 and the second color control hole CH2, respectively (refer to FIGS. 2 and 3).

As described with reference to FIG. 5, the surface treatment region SR may be formed from the perimeter HP of each of the first color control hole CH1 and the second color control hole CH2. The surface treatment region SR may include the first surface treatment region SR1 and the second surface treatment region SR2. The first surface treatment region SR1 and the second surface treatment region SR2 may include the hole perimeter HP and the outermost perimeter SRP, respectively.

A first bottom surface BS1 of the first color control hole CH1 may have a first center C1. A second bottom surface BS2 of the second color control hole CH2 may have a second center C2.

A distance between the neighboring first color control hole CH1 and the second color control hole CH2 may be expressed as a width Db of the bank BK between the neighboring first color control hole CH1 and the second color control hole CH2.

The width Db of the bank BK may be a distance between intersection points where a virtual straight line from the first center C1 to the second center C2 meets the hole perimeters HP of the first color control hole CH1 and the second color control hole CH2.

A distance, a distance between surface treatment regions next (adjacent) to each other and surrounding different color control holes) between the surface treatment region SR extending from the hole perimeter HP of the first color control hole CH1 and the surface treatment region SR extending from the hole perimeter HP of the second color control hole CH2 may be expressed as a separation distance SD.

By embodiments, a portion of the top surface of the bank BK indicated by the separation distance SD may have a contact angle smaller than the first contact angle of the first surface treatment region SR1. In some embodiments, a contact angle of a remaining portion of the top surface of the bank BK excluding the surface treatment region SR may be smaller than the first contact angle. In some embodiments, a contact angle of a side surface of the bank BK defining a sidewall of the color control hole CH may be smaller than the first contact angle.

The surface treatment regions SR next (adjacent) to each other may not meet or may not be merged with each other, but may be separated with the separation distance SD interposed therebetween. Accordingly, color disturbance caused when color control layer materials of different colors from each other are mixed may be prevented.

A distance of the surface treatment region SR may be a distance from t intersection point where the virtual straight line from the first center C1 to the second center C2 meets the hole perimeter HP of the first color control hole CH1 or the second color control hole CH2 in a direction (a radial direction) from the first center C1 to the second center C2.

A distance of the surface treatment region SR extended from the first color control hole CH1 may be expressed as a first distance Ds1, and a distance of the surface treatment region SR extended from the second color control hole CH2 may be expressed as a second distance Ds2. A distance excluding the first distance Ds1 and the second distance Ds2 from the width Db of the bank BK may be defined as the separation distance SD.

In embodiments, each of the first distance Ds1 and the second distance Ds2 may be less than ½ of the width of the bank BK. Accordingly, neighboring surface treatment regions SR may be separated from each other with the separation distance SD interposed therebetween, and color mixing for each pixel may be prevented.

In some embodiments, each of the first distance Ds1 and the second distance Ds2 may be in a range from 10% to 48%, from 20% to 45%, or from 30% to 45% of the width of the bank BK.

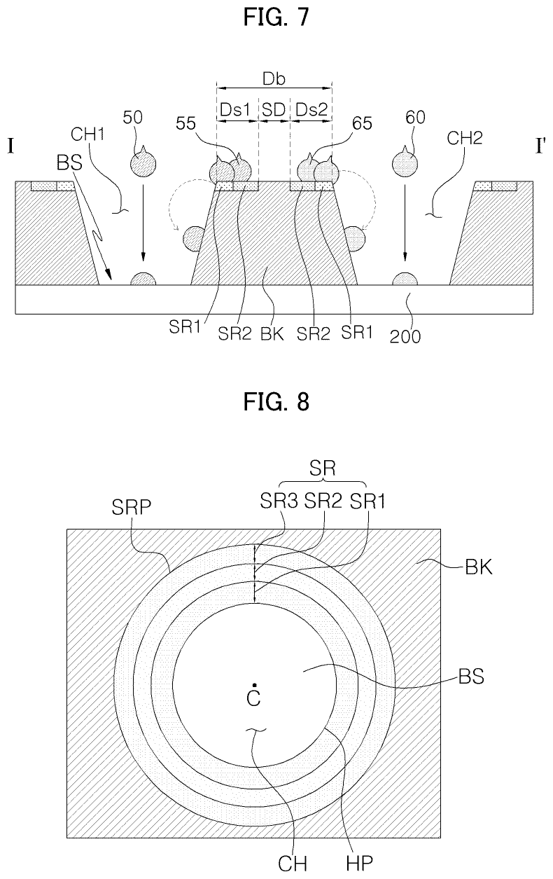

FIG. 7 is a schematic cross-sectional view illustrating an embodiment of formation of a color control layer.

Referring to FIG. 7, the first color control layer CR and the second color control layer CG may be formed by supplying a first colorant droplet 50 and a second colorant droplet 60 to the first color control hole CH1 and the second color control hole CH2, respectively by an ink jet process. The droplets 50 and 60 entering an inside of the hole perimeter HP may fall to the bottom surfaces BS of the color control holes CH1 and CH2 to form the color control layers CR and CG.

As the resolution of the display device increases and critical dimensions of the color control holes CH1 and CH2 decrease, failed droplets 55 and 65 that may fall to the top surface of the bank BK may be generated.

A failed first colorant droplet 55 and a failed second colorant droplet 65 may be guided into the first color control hole CH1 and the second color control hole CH2, respectively, by a contact angle property that sequentially decreases from the second surface treatment region SR2 to the first surface treatment region SR1. Thus, substantial self-alignment of colorant droplet may be implemented.

Further, as described above, neighboring surface treatment regions SR (e.g., neighboring second surface treatment regions SR2) may be separated by the separation distance SD. Accordingly, entrance of the failed first colorant droplet 55 into the second color control hole CH2 and/or the entrance of the failed second colorant droplet 65 into the first color control hole CH1 may be prevented.

Thus, a high-resolution/fine-dimension color control portion may be manufactured with relatively high reliability while preventing non-filling of each color control hole CH1 and CH2 and color mixing between the color control holes CH1 and CH2.

FIG. 8 is a schematic plan view illustrating an embodiment of a color control hole and a top surface of a bank.

Referring to FIG. 8, at least three surface treatment regions may be formed from the hole perimeter HP of the color control hole CH. In some embodiments, a first surface treatment region SR1, a second surface treatment region SR2, and a third surface treatment region SR3 may be sequentially formed in a direction from the hole perimeter HP toward the outermost perimeter SRP. A contact angle (a third contact angle) of the third surface treatment region SR3 may be greater than a contact angle (a second contact angle) of the second surface treatment region SR2. The contact angle of the second surface treatment region SR2 may be greater than a contact angle (a first contact angle) of the first surface treatment region SR1.

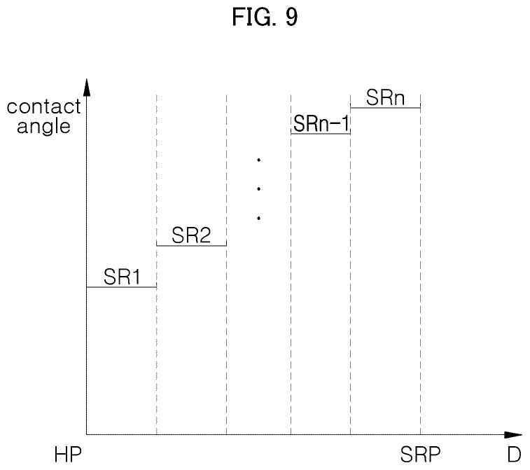

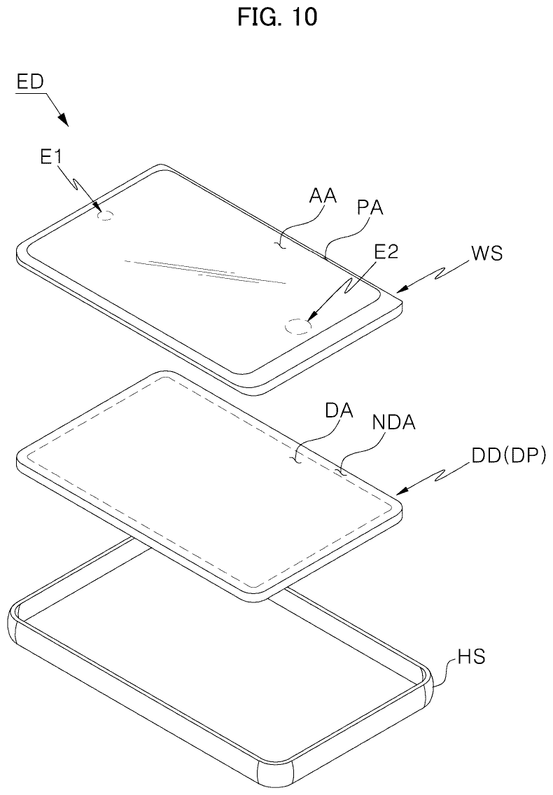

FIG. 9 is a graph illustrating an embodiment of a contact angle profile of a surface treatment region.

Referring to FIG. 9, a plurality of surface treatment regions may be sequentially formed while a distance D increases from a point of the hole perimeter HP of the color control hole CH to a point of the outermost perimeter SRP in a radial direction. In an embodiment, first to n^{th} surface treatment region Sr1 to SRn may be sequentially formed, for example. N may be an integer greater than or equal to 4.

In embodiments, contact angles of the first surface treatment region SR1 to the n^{th} surface treatment region SRn may sequentially increase. In an embodiment, as shown in FIG. 9, the contact angles from the first surface treatment region SR1 to the n surface treatment region SRn may increase stepwise, for example. Accordingly, self-induced/self-alignment of the droplet described with reference to FIG. 7 may be more effectively implemented.

In some embodiments, the contact angles of the first surface treatment region SR1 to the n^{th} surface treatment region SRn may increase continuously. In an embodiment, a graph of the contact angles from the first surface treatment region SR1 to the n^{th} surface treatment region SRn may be shown as a straight line bent at an interface of surface treatment regions next (adjacent) to each other. In an embodiment, a graph of the contact angles from the first surface treatment region SR1 to the n^{th} surface treatment region SRn may be shown as a positive slope straight line, an increasing concave curve, or an increasing convex curve.

FIG. 10 is an exploded perspective view illustrating an embodiment of an electronic device.

By embodiments, the electronic device may be implemented in the form of a mobile phone (smart phone), a tablet, a personal computer, or the like, including the above-described display device.

Referring to FIG. 10, the electronic device may include a window structure WS, a display panel DP, and a housing HS. The display device DD may include a display panel DP including the transistors and the light-emitting devices LE (refer to FIG. 3) as described above. The housing HS, the display device DD, and the window structure WS may be sequentially stacked along the third direction.

The window structure WS may provide an external display surface recognized by a user, such as a viewing surface of a mobile phone, and may include a transparent material film. In an embodiment, the window structure WS may include glass (e.g., ultra-thin glass (“UTG”)), a hard coating film, a plastic film, or the like, for example.

An outer surface of the window structure WS may include an active area AA and a peripheral area PA. The active area AA may provide a surface from which an image of the display device DD is substantially displayed and to which a user's touch/command is input. The peripheral area PA may substantially correspond to a bezel area of the display device.

The display device DD or the display panel DP may include a display area DA and a non-display area NDA. The display area DA of the display panel DP may substantially correspond to or overlap the active area AA of the window structure WS. The non-display area NDA of the display panel DP may substantially correspond to or overlap the peripheral area PA of the window structure WS.

In some embodiments, functional device areas E1 and E2 may be included in the active area AA of the window structure WS. In an embodiment, a first functional device area E1 may be included at one end portion of the active area AA and may be implemented, e.g., in the form of a camera hole, for example. The second functional device area E2 may serve as a fingerprint sensing area.

In an embodiment, a sensor structure for a touch sensing or a fingerprint sensing may be disposed in the display panel DP or between the window structure WS and the display panel DP, for example.

The housing HS may serve as a frame structure or a rear housing of the display device DD or the electronic device ED. A cover panel may be disposed between the housing HS and the display panel DP. The housing HS or the cover panel may include a plate (e.g., a steel use stainless (“SUS”) plate) that supports the display panel DP, the printed circuit board 300 (refer to FIG. 1), or the like. The housing HS or the cover panel may include an elastic body for absorbing shock of the display device DD.

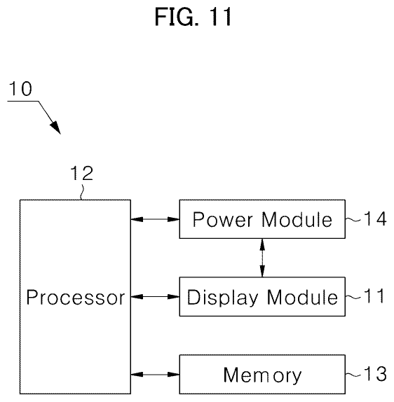

FIG. 11 is a block diagram of an embodiment of an electronic device.

Referring to FIG. 11, an electronic device 10 in an embodiment may include a display module 11, a processor 12, a memory 13 and a power module 14.

The processor 12 may include a central processing unit (“CPU”), an application processor (“AP”), a graphic processing unit (“GPU”), a communication processor (“CP”), an image signal processor (“ISP”) and/or a controller.

Data information for an operation of the processor 12 or the display module 11 may be stored in the memory 13. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts a power supplied by the power supply module to a generate power desired for the operation of the electronic device 10.

At least one of components of the electronic device 10 as described above may be included in the display device according to the above-described embodiments. Additionally, some of individual modules functionally included in one module may be included in the display device, and others may be provided separately from the display device. In an embodiment, the display module 11 may include the display device, and the processor 12, the memory 13 and the power module 14 may be provided in the form of another device in the electronic device 10 different from the display device, for example.

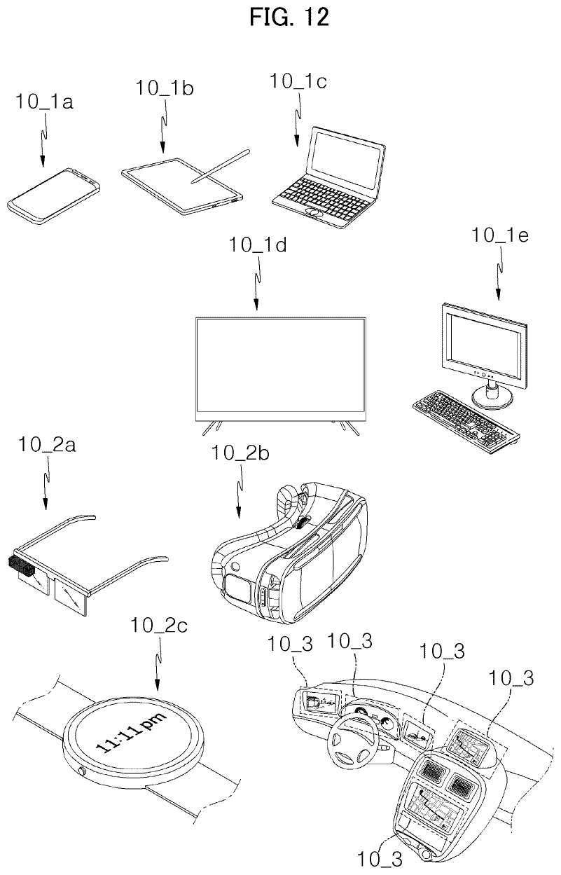

FIG. 12 is a schematic diagram of an embodiment of electronic devices

Referring to FIG. 12, non-limiting embodiments of various electronic devices to which the display device according to the above-described embodiments is applied include an electronic device for displaying an image such as a smartphone 10_1a, a tablet personal computer 10_1b, a laptop 10_1c, a television (“TV”) 10_1d, a desk monitor 10_1e, or the like; a wearable electronic device including a display module such as smart glasses 10_2a, a head mounted display 10_2b, a smart watch 10_2c, or the like; a vehicle electronic device 10_3 including a display module such as a center information display (“CID”) disposed at a vehicle instrument panel, a center fascia, a dashboard, etc., a head-up display, a room mirror display, or the like. The electronic device may include a virtual reality glass or an augmented reality glass.

What is claimed is:

1. A display device comprising:
a light-emitting device; and
a color control portion disposed on the light-emitting device, the color control portion comprising:
a bank in which a color control hole is defined, the bank including
a top surface including:
a surface treatment region including:
a first surface treatment region disposed next to a hole perimeter of the color control hole and having a first contact angle; and
a second surface treatment region spaced apart from the hole perimeter with the first surface treatment region interposed therebetween and having a second contact angle greater than the first contact angle; and
a color control layer formed in the color control hole.

2. The display device of claim 1, wherein the first surface treatment region includes the hole perimeter, and the second surface treatment region includes an outermost perimeter of the surface treatment region.

3. The display device of claim 1, wherein the second surface treatment region and the first surface treatment region contact each other.

4. The display device of claim 1, wherein the surface treatment region further comprises a third surface treatment region spaced apart from the first surface treatment region with the second surface treatment region therebetween, and the third surface treatment region has a third contact angle greater than the second contact angle of the second surface treatment region.

5. The display device of claim 4, wherein the first surface treatment region includes the hole perimeter, and the third surface treatment region includes an outermost perimeter of the surface treatment region.

6. The display device of claim 1, wherein the color control hole comprises a first color control hole and a second color control hole next to each other, and
the color control layer comprises a first color control layer and a second color control layer having different colors from each other and filling the first color control hole and the second color control hole, respectively.

7. The display device of claim 6, wherein the surface treatment region is provided in plural, and
a surface treatment region surrounding the first color control hole among surface treatment regions and a surface treatment region surrounding the second color control hole among the surface treatment regions are separated with a separation distance interposed therebetween on a portion of the top surface of the bank between the first color control hole and the second color control hole.

8. The display device of claim 7, wherein a portion of the top surface of the bank included in the separation distance has a contact angle smaller than the first contact angle.

9. The display device of claim 7, wherein a distance of the surface treatment region extended from a hole perimeter of the first color control hole and a distance of the surface treatment region extended from a hole perimeter of the second color control hole are each less than ½ of a width of the portion of the top surface of the bank between the first color control hole and the second color control hole.

10. The display device of claim 1, wherein the color control hole comprises a first color control hole, a second color control hole and a third color control hole, and
the color control layer includes a first color control layer, a second color control layer and a third color control layer having different colors from each other and filling the first color control hole, the second color control hole and the third color control hole, respectively.

11. The display device of claim 10, wherein the first color control layer, the second color control layer and the third color control layer serve as a red color layer, a green color layer and a blue color layer, respectively.

12. The display device of claim 11, wherein an area of the third color control layer is smaller than an area of each of the first color control layer and the second color control layer.

13. The display device of claim 11, wherein the color control portion further comprises:
a base layer on which the bank and the color control layer are arranged; and
a light-scattering layer disposed between the color control layer and the base layer to selectively overlap the first color control layer and the second color control layer among the first color control layer, the second color control layer and the third color control layer.

14. The display device of claim 1, which the display device does not include a polarizing plate.

15. A display device comprising:
a light-emitting device; and
a color control portion disposed on the light-emitting device, the color control portion comprising:
a bank in which a color control hole is defined, the bank comprising:
a top surface including:
a surface treatment region having a contact angle which increases in a region farther from a hole perimeter of the color control hole in a radial direction of the color control hole; and
a color control layer formed in the color control hole.

16. The display device of claim 15, wherein the surface treatment region is provided in plural, and
a plurality of surface treatment regions have contact angles which increase stepwise from the hole perimeter.

17. The display device of claim 15, wherein the contact angle of the surface treatment region continuously increases from the hole perimeter.

18. The display device of claim 15, wherein the surface treatment region provided in plural,
the color control hole is provided in plural,
a plurality of color control holes are surrounded by a plurality of surface treatment regions, respectively, and
the surface treatment regions are spaced apart from each other on the top surface of the bank.

19. An electronic device comprising:
a display device comprising:
a light-emitting device; and
a color control portion disposed on the light-emitting device, the color control portion comprising:
a bank in which a color control hole is defined, the bank comprising:
a top surface including:
a surface treatment region comprising:
a first surface treatment region disposed next to a hole perimeter of the color control hole and having a first contact angle; and
a second surface treatment region spaced apart from the hole perimeter with the first surface treatment region interposed therebetween, and having a second contact angle greater than the first contact angle; and
a color control layer formed in the color control hole;
a memory; and
a processor which executes data included in the memory and controls an operation of the display device.

20. The electronic device of claim 19, wherein the electronic device includes virtual reality or augmented reality glasses, a smartphone, a tablet personal computer, a laptop, a television, a desk monitor, smart glasses, a head-mounted display, a smart watch, or a vehicle display.
